(19) United States
(12) Patent Application Publication
(10) Pub. No.: US 2024/0096908 A1
(43) Pub. Date: Mar. 21, 2024

(54) ARRAY SUBSTRATE

(71) Applicant: Wuhan China Star Optoelectronics Technology Co., Ltd., Wuhan, Hubei (CN)

(72) Inventors: Fuhsiung TANG, Wuhan, Hubei (CN); Yanqing GUAN, Wuhan, Hubei (CN); Congxing YANG, Wuhan, Hubei (CN)

(73) Assignee: Wuhan China Star Optoelectronics Technology Co., Ltd., Wuhan, Hubei (CN)

(21) Appl. No.: 17/289,899

(22) PCT Filed: Apr. 15, 2021
(86) PCT No.: PCT/CN2021/087433

§ 371 Date: Dec. 11, 2023

(30) Foreign Application Priority Data
Jan. 12, 2021 (CN) 202110034906.5
Apr. 2, 2021 (CN) 202110360378.2

(51) Int. Cl. H01L 27/12; H01L 29/786

(52) U.S. Cl. CPC H01L 27/1244; H01L 29/78633

(57) ABSTRACT

An array substrate is provided. The array substrate includes a substrate, a light-shielding layer, and an active layer. The light-shielding layer is disposed on the substrate, and the active layer is disposed on the light-shielding layer. Wherein, an orthographic projection of the active layer on the substrate is positioned within an orthographic projection of the light-shielding layer on the substrate. The present disclosure prevents the active layer from forming ramps and then breaking by allowing the orthographic projection of the active layer on the substrate to be positioned within the orthographic projection of the light-shielding layer on the substrate, thereby ensuring performances of the array substrate.

### FIELD OF INVENTION

The present disclosure relates to the field of display technologies, and more particularly, to an array substrate.

### BACKGROUND OF INVENTION

At present, active layers are usually sensitive to optical signals (such as backlight sources of display devices), and different optical signals will cause currents of thin film transistors to dramatically increase when in an off state. When current signals are large enough, a switch ratio of the thin film transistors will decrease, which further causes thin film transistor arrays to be turned on abnormally and finally causes display pictures to be abnormal. At present, a method usually adopted is to add light-shielding layers under a bottom of channel regions to block influences of the backlight sources on the thin film transistors. However, the active layers will form ramps at junctions with and without the light-shielding layers. In addition, material of the active layers is non-flexible material, due to this phenomenon of forming the ramps, when the active layers undergo subsequent etching and laser annealing, the active layers are prone to become narrow or have defects of fractures, thereby causing a yield loss and further affecting performances of array substrates.

### Technical Problem

Technical problem: an embodiment of the present disclosure provides an array substrate to solve a problem of the active layers having ramps and then causing fractures at the junctions between the light-shielding layers and the active layers, thereby improving performances of the array substrate.

### SUMMARY OF INVENTION

An embodiment of the present disclosure provides an array substrate, which includes:
a substrate;
a light-shielding layer disposed on the substrate; and
an active layer disposed on the light-shielding layer, wherein, an orthographic projection of the active layer on the substrate is positioned within an orthographic projection of the light-shielding layer on the substrate.

Optionally, in some embodiments of the present disclosure, the light-shielding layer includes a first light-shielding part, a second light-shielding part, and a third light-shielding part connected to each other in sequence, and the first light-shielding part and the third light-shielding part are positioned on a same side of the second light-shielding part and opposite to each other.

Optionally, in some embodiments of the present disclosure, the active layer includes a first active part, a second active part, and a third active part connected to each other in sequence, the first active part is disposed on the first light-shielding part, the second active part is disposed on the second light-shielding part, and the third active part is disposed on the third light-shielding part.

Optionally, in some embodiments of the present disclosure, the first active part includes first conducting regions and a first channel region, the first conducting regions are disposed on both ends of the first channel region, the third active part includes second conducting regions and a second channel region, and the second conducting regions are disposed on both ends of the second channel region.

Optionally, in some embodiments of the present disclosure, the first conducting regions include first doped regions and second doped regions, the first doped regions are disposed on the both ends of the first channel region, the second doped regions are disposed on both ends of the first doped regions away from the first channel region, and a doping concentration of the first doped regions is less than a doping concentration of the second doped regions.

Optionally, in some embodiments of the present disclosure, the second conducting regions include third doped regions and fourth doped regions, the third doped regions are disposed on the both ends of the second channel region, the fourth doped regions are disposed on both ends of the third doped regions away from the second channel region, and a doping concentration of the third doped regions is less than a doping concentration of the fourth doped regions.

Optionally, in some embodiments of the present disclosure, a planar shape of the first light-shielding part is provided with a first protrusion, a protruding direction of the first protrusion is perpendicular to an extending direction of the first channel region, and the first protrusion is positioned in an area of the first light-shielding part corresponding to the first doped regions; and a planar shape of the third light-shielding part is provided with a second protrusion, a protruding direction of the second protrusion is perpendicular to an extending direction of the second channel region, and the second protrusion is positioned in an area of the third light-shielding part corresponding to the third doped regions.

Optionally, in some embodiments of the present disclosure, an edge of an orthographic projection of an area of the active layer excluding the first doped regions and the third doped regions overlaps an edge of the orthographic projection of the light-shielding layer.

Optionally, in some embodiments of the present disclosure, the light-shielding layer further includes a fourth light-shielding part connected to the first light-shielding part, the second light-shielding part, and the third light-shielding part.

Optionally, in some embodiments of the present disclosure, the first light-shielding part, the third light-shielding part, and the fourth light-shielding part are positioned on the same side of the second light-shielding part, and the fourth light-shielding part is disposed between the first light-shielding part and the third light-shielding part.

Optionally, in some embodiments of the present disclosure, the light-shielding layer includes a first light-shielding part, a second light-shielding part, and a third light-shielding part connected to each other in sequence, and the first light-shielding part and the third light-shielding part are positioned on different sides of the second light-shielding part.

Optionally, in some embodiments of the present disclosure, the active layer includes a first active part, a second active part, and a third active part connected to each other in sequence, the first active part is disposed on the first light-shielding part, the second active part is disposed on the second light-shielding part, and the third active part is disposed on the third light-shielding part.

Optionally, in some embodiments of the present disclosure, the second active part includes third conducting regions and a third channel region, the third conducting regions are disposed on both ends of the third channel region, and the first active part and the third active part are fourth conducting regions.

Optionally, in some embodiments of the present disclosure, the second light-shielding part is provided with a third protrusion, a protruding direction of the third protrusion is perpendicular to an extending direction of the third channel region, and the third protrusion is positioned in an area of the second light-shielding part corresponding to the third conducting regions.

Optionally, in some embodiments of the present disclosure, an edge of an orthographic projection of an area of the active layer excluding the third conducting regions overlaps an edge of the orthographic projection of the light-shielding layer.

Optionally, in some embodiments of the present disclosure, a doping concentration of the third channel region is less than a doping concentration of the third conducting regions, and the doping concentration of the third conducting regions is less than a doping concentration of the fourth conducting regions.

Optionally, in some embodiments of the present disclosure, a distance from an edge of an orthographic projection of the third conducting regions on the substrate to an edge of the orthographic projection of the light-shielding layer on the substrate ranges from 400 nm to 2,000 nm.

Optionally, in some embodiments of the present disclosure, distances from an edge of an orthographic projection of the first doped regions on the substrate and an edge of an orthographic projection of the third doped regions on the substrate to an edge of the orthographic projection of the light-shielding layer on the substrate both range from 400 nm to 2,000 nm.

Optionally, in some embodiments of the present disclosure, a distance from an edge of the orthographic projection of the active layer on the substrate to an edge of the orthographic projection of the light-shielding layer on the substrate ranges from 0 nm to 6,000 nm.

Optionally, in some embodiments of the present disclosure, a thickness of the active layer ranges from 30 nm to 70 nm.

### Advantageous Effect of Invention

Beneficial effect: the present disclosure provides the array substrate, which includes the substrate, the light-shielding layer, and the active layer. The light-shielding layer is disposed on the substrate, and the active layer is disposed on the light-shielding layer. Wherein, the orthographic projection of the active layer on the substrate is positioned within the orthographic projection of the light-shielding layer on the substrate. The present disclosure prevents the active layer from forming ramps and then breaking by allowing the orthographic projection of the active layer on the substrate to be positioned within the orthographic projection of the light-shielding layer on the substrate, thereby ensuring performances of the array substrate.

### DESCRIPTION OF DRAWINGS

The following detailed description of specific embodiments of the present disclosure will make the technical solutions and other beneficial effects of the present disclosure obvious with reference to the accompanying drawings.

FIG. 1 is a schematic top view of an array substrate in current technology.

FIG. 2 is a schematic cross-sectional diagram of the array substrate along a line AB in FIG. 1.

FIG. 3 is a schematic top view of an array substrate according to a first embodiment of the present disclosure.

FIG. 4 is a schematic cross-sectional diagram of the array substrate along a line CD in FIG. 3.

FIG. 5 is a schematic top view of the array substrate according to a second embodiment of the present disclosure.

FIG. 6 is a schematic cross-sectional diagram of the array substrate along a line DE in FIG. 5.

FIG. 7 is a schematic top view of the array substrate according to a third embodiment of the present disclosure.

FIG. 8 is a schematic top view of the array substrate according to a fourth embodiment of the present disclosure.

FIG. 9 is a schematic cross-sectional diagram of the array substrate along a line EF in FIG. 8.

FIG. 10 is a schematic top view of the array substrate according to a fifth embodiment of the present disclosure.

FIG. 11 is a schematic top view of the array substrate according to a sixth embodiment of the present disclosure.

FIG. 12 is a flowchart of a manufacturing method of the array substrate according to an embodiment of the present disclosure.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure.

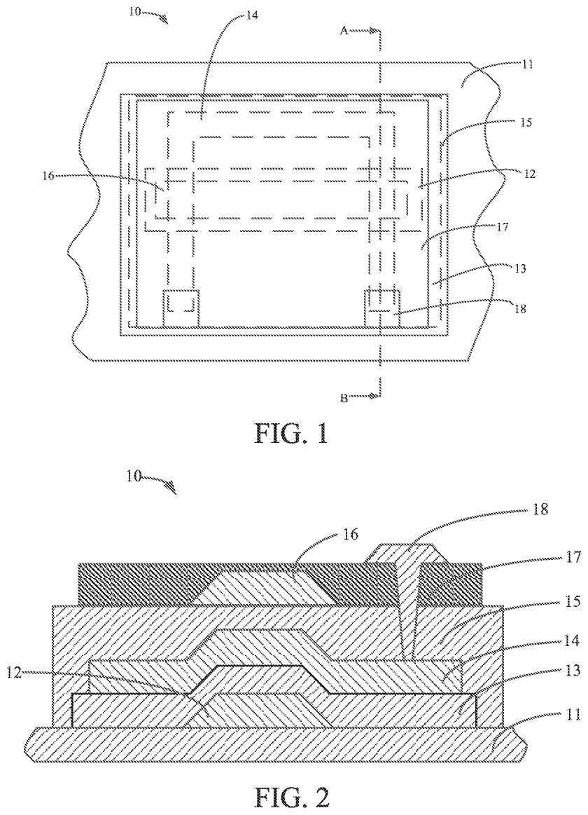

Referring to FIGS. 1 and 2, FIG. 1 is a schematic top view of an array substrate in current technology. FIG. 2 is a schematic cross-sectional diagram of the array substrate along a line AB in FIG. 1. The array substrate 10 in the current technology includes a substrate 11, a light-shielding layer 12, a buffer layer 13, an active layer 14, an insulating layer 15, a gate electrode 16, a passivation layer 17, and a source and drain electrode layer 18. The buffer layer 13 is disposed on the light-shielding layer 12. The active layer 14 is disposed on the buffer layer 13. The insulating layer 15 completely covers the active layer 14. The gate electrode 16 is disposed on the insulating layer 15. The passivation layer 17 covers the insulating layer 15 and the gate electrode 16, and the source and drain electrode layer 18 is disposed on the passivation layer 17 and is electrically connected to the active layer 14. In the array substrate 10 provided by the current technology, the active layer 14 will form ramps above junctions with and without the light-shielding layer 12, thereby causing a thickness of the active layer 14 to be uneven and even causing the active layer 14 to have a risk of breaking, thereby affecting performances of the array substrate.

Therefore, the present disclosure provides an array substrate to solve the problem existing in the array substrate in the current technology.

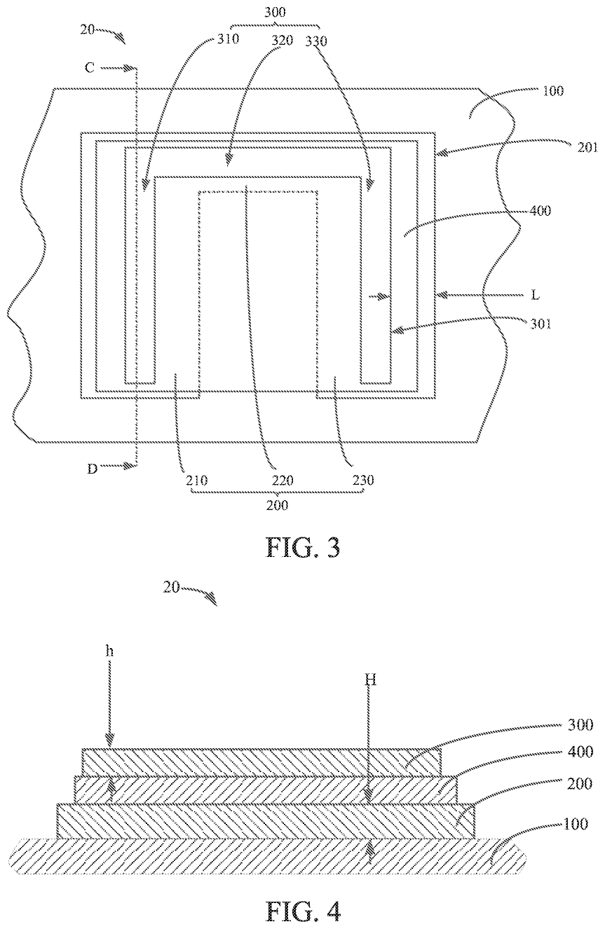

Referring to FIGS. 3 and 4, FIG. 3 is a schematic top view of an array substrate according to a first embodiment of the present disclosure. FIG. 4 is a schematic cross-sectional diagram of the array substrate along a line CD in FIG. 3. The present disclosure provides the array substrate 20. The array substrate 20 includes a substrate 100, a light-shielding layer 200, and an active layer 300. The specific description is as follows.

A material of the substrate 100 may be polyimide or glass.

The light-shielding layer 200 is disposed on the substrate 100. The light-shielding layer 200 includes a first light-shielding part 210, a second light-shielding part 220, and a third light-shielding part 230 connected to each other in sequence. The first light-shielding part 210 and the third light-shielding part 230 are positioned on a same side of the second light-shielding part 220 and are disposed opposite to each other. A material of the light-shielding layer 200 includes a metal material and an insulating material. Wherein, the metal material may be one or more combinations of Al, Cu, Ag, Au, Mn, Zn, or Fe, and the insulating material includes one or more combinations of SiNₓ, SiOₓ, or SiOₓN_{y}. A thickness H of the light-shielding layer 200 ranges from 50 nm to 500 nm. Specifically, the thickness H of the light-shielding layer 200 may be 50 nm, 52 nm, 70 nm, 200 nm, 350 nm, 430 nm, 470 nm, 490 nm, or 500 nm. A shape of the light-shielding layer 200 may be square, rectangular, or circular.

In the present disclosure, the first light-shielding part 210 and the third light-shielding part 230 are positioned on the same side of the second light-shielding part 220, thereby simplifying a manufacturing process and reducing production cost.

In an embodiment, a surface of the light-shielding layer 200 facing the substrate 100 is a rough surface, the rough surface is configured to reflect light which is emitted from backlight sources to the light-shielding layer 200 back to the backlight sources, thereby reducing light loss and improving a light-shielding effect of the light-shielding layer 200.

In an embodiment, the array substrate 20 further includes a buffer layer 400. The buffer layer 400 is disposed on the light-shielding layer 200. The buffer layer 400 includes one or more combinations of SiNₓ, SiOₓ, or SiOₓN_{y}.

The active layer 300 is disposed on the light-shielding layer 200.

Specifically, the active layer 300 is disposed on the buffer layer 400. In an embodiment, a thickness h of the active layer 300 ranges from 30 nm to 70 nm. The thickness h of the active layer 300 may be 30 nm, 31 nm, 35 nm, 38 nm, 46 nm, 50 nm, 60 nm, 64 nm, 68 nm, or 70 nm.

In an embodiment, a material of the active layer 300 includes one of amorphous silicon or polysilicon.

In an embodiment, an orthographic projection 301 of the active layer 300 on the substrate 100 is positioned within an orthographic projection 201 of the light-shielding layer 200 on the substrate 100.

In an embodiment, a distance L from an edge of the orthographic projection 301 of the active layer 300 on the substrate 100 to an edge of the orthographic projection 201 of the light-shielding layer 200 on the substrate 100 ranges from 0 nm to 6,000 nm. Specifically, the distance L from the edge of the orthographic projection 301 of the active layer 300 on the substrate 100 to the edge of the orthographic projection 201 of the light-shielding layer 200 on the substrate 100 may be 0 nm, 0.1 nm, 1 nm, 10 nm, 1,000 nm, 2,500 nm, 4,000 nm, 5,000 nm, 5,800 nm, or 6,000 nm.

In an embodiment, when the distance L from the edge of the orthographic projection 301 of the active layer 300 on the substrate 100 to the edge of the orthographic projection 201 of the light-shielding layer 200 on the substrate 100 is set to be 0 nm, the light-shielding layer 200 can be allowed to exactly cover the active layer 300, thereby reducing cost.

In an embodiment, the active layer 300 includes a first active part 310, a second active part 320, and a third active part 330 connected to each other in sequence. The first active part 310 is disposed on the first light-shielding part 210. The second active part 320 is disposed on the second light-shielding part 220. The third active part 330 is disposed on the third light-shielding part 230.

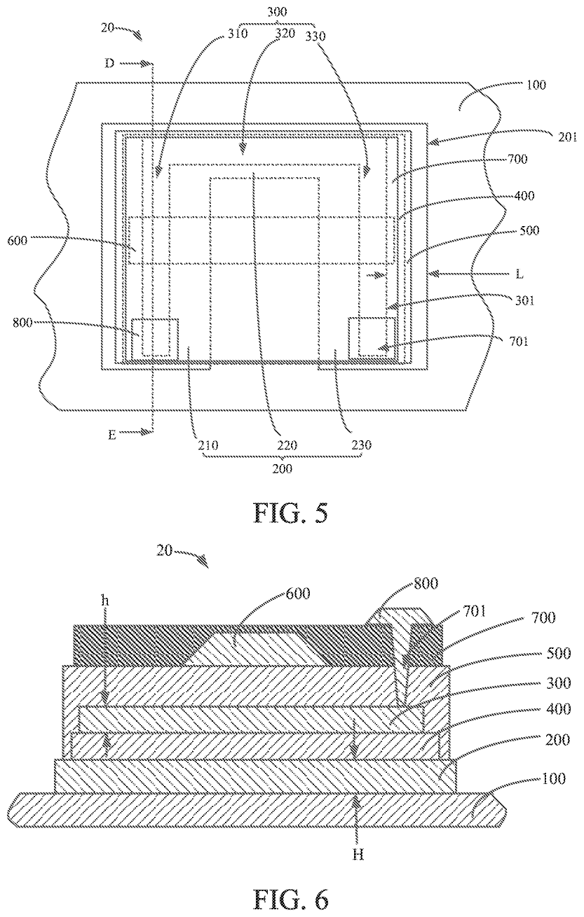

Referring to FIGS. 5 and 6, FIG. 5 is a schematic top view of the array substrate according to a second embodiment of the present disclosure. FIG. 6 is a schematic cross-sectional diagram of the array substrate along a line DE in FIG. 5. It should be noted that a difference between the second embodiment and the first embodiment is that:

the array substrate 20 further includes an insulating layer 500, a gate electrode 600, a passivation layer 700, and a source and drain electrode layer 800. The insulating layer 500 covers the active layer 300. A material of the insulating layer 500 includes one or more combinations of SiO2 or SiₓN_{y}. The gate electrode 600 is disposed on the insulating layer 500 and is positioned on the first active part 310 and the third active part 330. A material of the gate electrode 600 includes one or more combinations of Al, Cu, Ag, Au, Mn, Zn, or Fe. The passivation layer 700 covers the insulating layer 500 and the gate electrode 600. The passivation layer 700 is defined with a through-hole 701. The through-hole 701 penetrates through the passivation layer 700 and the insulating layer 500 to expose the active layer 300. The source and drain electrode layer 800 is disposed on the passivation layer 700 and extends into the through-hole 701 to be electrically connected to the active layer 300. A material of the source and drain electrode layer 800 includes one or more combinations of Al, Cu, Ag, Au, Mn, Zn, or Fe.

In the present disclosure, by allowing the orthographic projection of the active layer on the substrate to be positioned within the orthographic projection of the light-shielding layer on the substrate, that is, disposing an entire light-shielding layer under the active layer, a phenomenon of the active layer forming ramps and then breaking or the active layer having an uneven thickness can be prevented, thereby preventing electrical deterioration of the array substrate and ensuring performances of the array substrate. In addition, since the active layer is shielded by the light-shielding layer, the thickness of the light-shielding layer can be thickened to further improve the light-shielding effect of the light-shielding layer, thereby ensuring the performances of the array substrate. Since entire active layer is disposed on the light-shielding layer, a phenomenon of the active layer being narrower or breaking will not happen, and further in some special devices, a thinning restriction of the thickness of the active layer can be relaxed, thereby reducing the production cost.

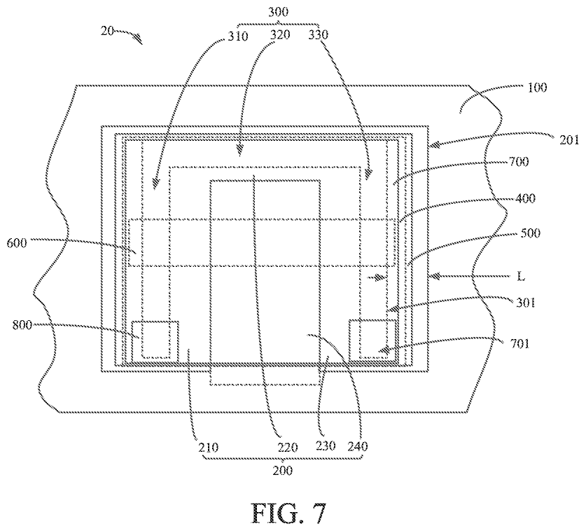

Referring to FIG. 7, FIG. 7 is a schematic top view of the array substrate according to a third embodiment of the present disclosure. It should be noted that a difference between the third embodiment and the second embodiment is that:

The light-shielding layer 200 further includes a fourth light-shielding part 240. The fourth light-shielding part 240 is connected to the first light-shielding part 210, the second light-shielding part 220, and the third light-shielding part 230. The first light-shielding part 210, the third light-shielding part 230, and the fourth light-shielding part 240 are positioned on the same side of the second light-shielding part 220, and the fourth light-shielding part 240 is disposed between the first light-shielding part 210 and the third light-shielding part 230. Other structures are as described in the second embodiment, and will not be repeated here.

In the present disclosure, the fourth light-shielding part 240 is disposed between the first light-shielding part 210 and the third light-shielding part 230 to increase a light-shielding range of the light-shielding layer 200 and further improve the light-shielding effect, thereby ensuring the performances of the array substrate 20.

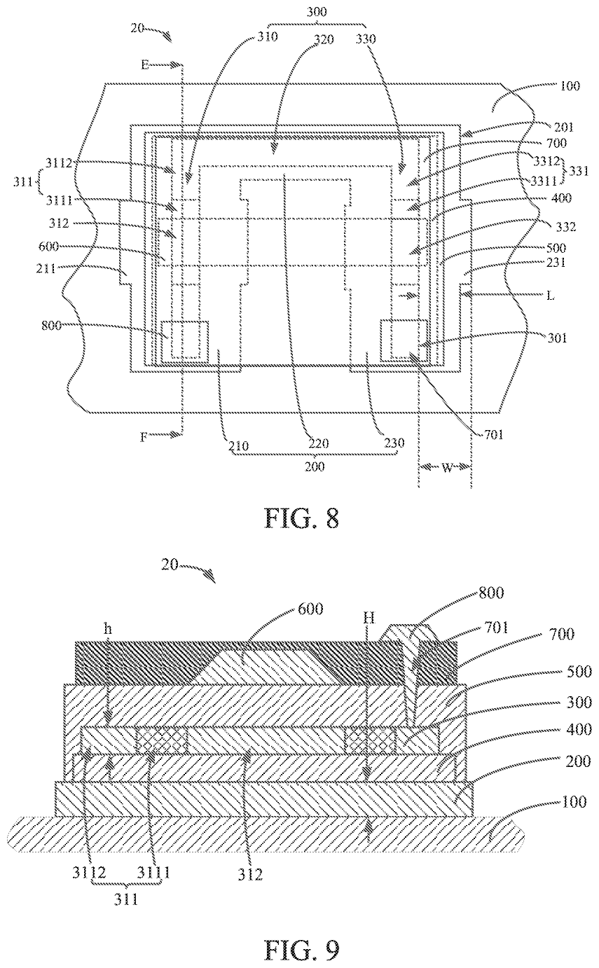

Referring to FIGS. 8 and 9, FIG. 8 is a schematic top view of the array substrate according to a fourth embodiment of the present disclosure. FIG. 9 is a schematic cross-sectional diagram of the array substrate along a line EF in FIG. 8. It should be noted that a difference between the fourth embodiment and the second embodiment is that:

The first active part 310 consists of first conducting regions 311 and a first channel region 312. The first conducting regions 311 are disposed on both ends of the first channel region 312.

In an embodiment, the third active part 330 consists of second conducting regions 331 and a second channel region 332. The second conducting regions 331 are disposed on both ends of the second channel region 332. The second active part 320 is a connecting and conducting region. The second active part 320 connects the first conducting regions 311 and the second conducting regions 331.

In an embodiment, the first conducting regions 311, the connecting and conducting region, and the second conducting regions 331 are doped with one or two combinations of phosphorus or arsenic, which changes resistances of the first conducting regions 311, the connecting and conducting region, the second conducting regions 331, and the array substrate 20, thereby improving the performances of the array substrate 20.

In an embodiment, the first conducting regions 311 include first doped regions 3111 and second doped regions 3112. The first doped regions 3111 are disposed on the both ends of the first channel region 312. The second doped regions 3112 are disposed on both ends of the first doped regions 3111 away from the first channel region 312. A doping concentration of the first doped regions 3111 is less than a doping concentration of the second doped regions 3112.

In an embodiment, the doping concentration of the first doped regions 3111 ranges from 3e¹²/cm² to 3e¹³/cm². The doping concentration of the second doped regions 3112 ranges from 3e¹⁴/cm² to 3e1⁵/cm².

In an embodiment, at least a distance W from an edge of an orthographic projection 301 of the first doped regions 3111 on the substrate 100 to an edge of the orthographic projection 201 of the light-shielding layer 200 on the substrate 100 ranges from 400 nm to 2,000 nm.

In the present disclosure, by at least setting the distance W from the edge of the orthographic projection 301 of the first doped regions 3111 on the substrate 100 to the edge of the orthographic projection 201 of the light-shielding layer 200 on the substrate 100 to range from 400 nm to 2,000 nm, the light-shielding layer 200 can be allowed to exactly cover the first doped regions 3111, thereby improving the light-shielding effect, improving aperture ratio of pixels, and reducing cost at a same time.

In an embodiment, at least distances W from the edge of the orthographic projection 301 of the first doped regions 3111 on the substrate 100 and an edge of an orthographic projection 301 of the first channel region 312 on the substrate 100 to the edge of the orthographic projection 201 of the light-shielding layer 200 on the substrate 100 both range from 400 nm to 2,000 nm. A distance L from an edge of the orthographic projection 301 of the active layer 300 on the substrate 100 to the edge of the orthographic projection 201 of the light-shielding layer 200 on the substrate 100 is set to be 0 nm.

In the present disclosure, by setting the distances W from the edge of the orthographic projection 301 of the first doped regions 3111 on the substrate 100 and the edge of the orthographic projection 301 of the first channel region 312 on the substrate 100 to the edge of the orthographic projection 201 of the light-shielding layer 200 on the substrate 100 both to range from 400 nm to 2,000 nm, the light-shielding layer 200 can be allowed to exactly cover the active layer 300, thereby improving the light-shielding effect, reducing cost, and preventing the active layer 300 from breaking at a same time.

In an embodiment, a doping concentration of the first channel region 312 is less than the doping concentration of the first doped regions 3111.

In an embodiment, the first channel region 312 is doped with one or two combinations of boron or gallium, which changes a resistance of the first channel region 312 but does not affect its own performances, thereby improving the performances of the array substrate 20.

In the present disclosure, the doping concentrations of the first doped regions 3111 and the second doped regions 3112 are set to be different, which allows the first doped regions 3111 to be resistance transition zones, thereby improving the performances of the array substrate 20.

In an embodiment, a planar shape of the first light-shielding part 210 is provided with a first protrusion 211. A protruding direction of the first protrusion 211 is perpendicular to a vertical extending direction of the first channel region 312. The first protrusion is positioned in an area of the first light-shielding part 210 corresponding to the first doped regions 3111.

In an embodiment, the planar shape of the first light-shielding part 210 is provided with the first protrusion 211. The protruding direction of the first protrusion 211 is perpendicular to the vertical extending direction of the first channel region 312. The first protrusion is positioned in an area of the first light-shielding part 210 corresponding to the first doped regions 3111 and the first channel region 312.

In an embodiment, the second conducting regions 331 include third doped regions 3311 and fourth doped regions 3312. The third doped regions 3311 are disposed on the both ends of the second channel region 332. The fourth doped regions 3312 are disposed on both ends of the third doped regions 3311 away from the second channel region 332. A doping concentration of the third doped regions 3311 is less than a doping concentration of the fourth doped regions 3312.

In an embodiment, the doping concentration of the third doped regions 3311 ranges from 3e¹²/cm² to 3e¹³/cm². The doping concentration of the fourth doped regions 3312 ranges from 3e¹⁴/cm² to 3e¹⁵/cm².

In an embodiment, a doping concentration of the second channel region 332 is less than the doping concentration of the third doped regions 3311.

In an embodiment, the second channel region 332 is doped with one or two combinations of boron or gallium, which changes a resistance of the second channel region 332 but does not affect its own performances, thereby improving the performances of the array substrate 20.

In the present disclosure, the doping concentrations of the third doped regions 3311 and the fourth doped regions 3312 are set to be different, which allows the third doped regions 3311 to be the resistance transition zones, thereby improving the performances of the array substrate 20.

In an embodiment, at least a distance W from an edge of an orthographic projection 301 of the third doped regions 3311 on the substrate 100 to the edge of the orthographic projection 201 of the light-shielding layer 200 on the substrate 100 ranges from 400 nm to 2,000 nm.

In the present disclosure, by at least setting the distance W from the edge of the orthographic projection 301 of the third doped regions 3311 on the substrate 100 to the edge of the orthographic projection 201 of the light-shielding layer 200 on the substrate 100 to range from 400 nm to 2,000 nm, the light-shielding layer 200 can be allowed to exactly cover the third doped regions 3311, thereby improving the light-shielding effect of the light-shielding layer 200 and reducing cost at a same time.

In an embodiment, at least distances W from the edge of the orthographic projection 301 of the third doped regions 3311 on the substrate 100 and an edge of an orthographic projection 301 of the second channel region 332 on the substrate 100 to the edge of the orthographic projection 201 of the light-shielding layer 200 on the substrate 100 both range from 400 nm to 2,000 nm. The distance L from the edge of the orthographic projection 301 of the active layer 300 on the substrate 100 to the edge of the orthographic projection 201 of the light-shielding layer 200 on the substrate 100 is set to be 0 nm.

In the present disclosure, by setting the distances W from the edge of the orthographic projection 301 of the third doped regions 3311 on the substrate 100 and the edge of the orthographic projection 301 of the second channel region 332 on the substrate 100 to the edge of the orthographic projection 201 of the light-shielding layer 200 on the substrate 100 both to range from 400 nm to 2,000 nm, the light-shielding layer 200 can be allowed to exactly cover the active layer 300, thereby further improving the light-shielding effect, preventing the active layer 300 from breaking, and reducing cost at the same time.

In an embodiment, a planar shape of the third light-shielding part 230 is provided with a second protrusion 231. A protruding direction of the second protrusion 231 is perpendicular to a vertical extending direction of the second channel region 332. The second protrusion is positioned in an area of the third light-shielding part 230 corresponding to the third doped regions 3311.

In an embodiment, the planar shape of the third light-shielding part 230 is provided with the second protrusion 231. The protruding direction of the second protrusion 231 is perpendicular to the vertical extending direction of the second channel region 332. The second protrusion 231 is positioned in an area of the third light-shielding part 230 corresponding to the third doped regions 3311 and the second channel region 332.

In an embodiment, an edge of an orthographic projection 301 of an area of the active layer 300 excluding the first doped regions 3111 and the third doped regions 3311 overlaps the edge of the orthographic projection 201 of the light-shielding layer 200. The area of the active layer 300 excluding the first doped regions 3111 and the third doped regions 3311 includes the second doped regions 3112, the second active part 320, and the fourth doped regions 3312.

In an embodiment, distances W from the edge of the orthographic projection 301 of the first doped regions 3111 on the substrate 100 and an edge of an orthographic projection 301 of the third doped regions 3311 on the substrate 100 to the edge of the orthographic projection 201 of the light-shielding layer 200 on the substrate 100 both range from 400 nm to 2,000 nm. Specifically, the distances W from the edge of the orthographic projection 301 of the first doped regions 3111 on the substrate 100 and the edge of the orthographic projection 301 of the third doped regions 3311 on the substrate 100 to the edge of the orthographic projection 201 of the light-shielding layer 200 on the substrate 100 may be 400 nm, 500 nm, 800 nm, 1,500 nm, 1,900 nm, or 2,000 nm. In this embodiment, the distances W from the edge of the orthographic projection 301 of the first doped regions 3111 on the substrate 100 and the edge of the orthographic projection 301 of the third doped regions 3311 on the substrate 100 to the edge of the orthographic projection 201 of the light-shielding layer 200 on the substrate 100 are 500 nm.

In the present disclosure, by setting the distances W from the edge of the orthographic projection 301 of the first doped regions 3111 on the substrate 100 and the edge of the orthographic projection 301 of the third doped regions 3311 on the substrate 100 to the edge of the orthographic projection 201 of the light-shielding layer 200 on the substrate 100 both to range from 400 nm to 2,000 nm, light incident on the first doped regions 3111 and the third doped regions 3311 can be shielded, which can further prevent electrical leakage of the active layer 300, thereby improving the performances of the array substrate 20.

In an embodiment, the gate electrode 600 is disposed on the first channel region 312 and the second channel region 332. The first doped regions 3111 and the third doped regions 3311 are disposed on one side of the buffer layer 400 adjacent to the gate electrode 600. The second doped regions 3112 and the fourth doped regions 3312 are disposed on one side of the buffer layer 400 away from the gate electrode 600.

In the present disclosure, the first doped regions 3111 and the third doped regions 3311 are lightly doped, and the second doped regions 3112, the fourth doped regions 3312, and the second active part 320 are heavily doped, which can prevent electrical leakage of the array substrate 20, thereby improving the performances of the array substrate 20.

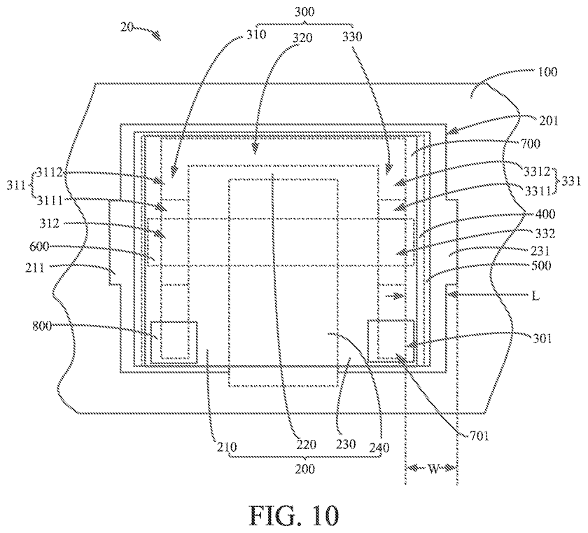

Referring to FIG. 10, FIG. 10 is a schematic top view of the array substrate according to a fifth embodiment of the present disclosure. It should be noted that a difference between the fifth embodiment and the fourth embodiment is that:

The light-shielding layer 200 further includes the fourth light-shielding part 240. The fourth light-shielding part 240 is connected to the first light-shielding part 210, the second light-shielding part 220, and the third light-shielding part 230. The first light-shielding part 210, the third light-shielding part 230, and the fourth light-shielding part 240 are positioned on the same side of the second light-shielding part 220, and the fourth light-shielding part 240 is disposed between the first light-shielding part 210 and the third light-shielding part 230. Other structures are as described in the fourth embodiment, and will not be repeated here.

In the present disclosure, the fourth light-shielding part 240 is disposed between the first light-shielding part 210 and the third light-shielding part 230 to increase the light-shielding range of the light-shielding layer 200 and further improve the light-shielding effect, thereby ensuring the performances of the array substrate 20.

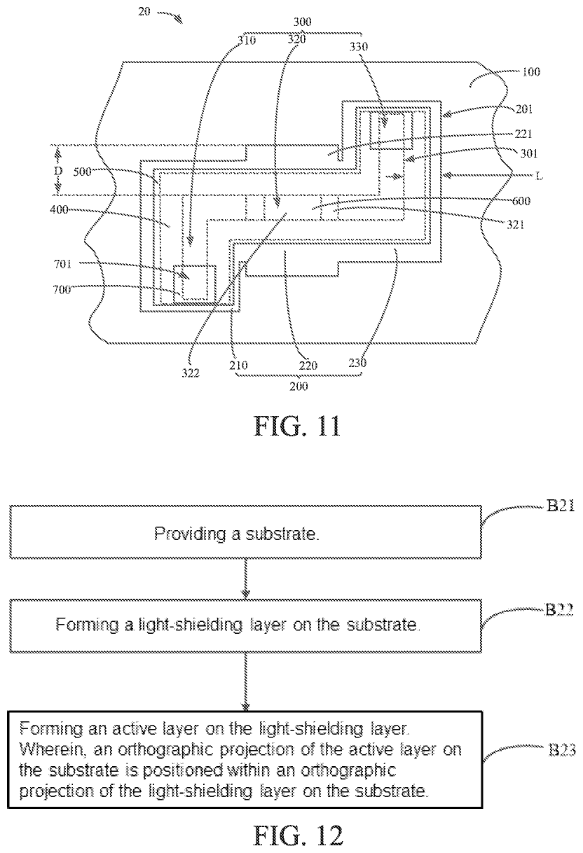

Referring to FIG. 11, FIG. 11 is a schematic top view of the array substrate according to a sixth embodiment of the present disclosure. It should be noted that a difference between the sixth embodiment and the fourth embodiment is that:

The first light-shielding part 210 and the third light-shielding part 230 are positioned on different sides of the second light-shielding part 220.

In an embodiment, the second active part 320 includes third conducting regions 321 and a third channel region 322. The third conducting regions 321 are disposed on both ends of the third channel region 322. The first active part 310 and the third active part 330 are fourth conducting regions. The third channel region 322 is doped with one or two combinations of boron or gallium, which changes a resistance of the third channel region 322 but does not affect its own performances, thereby improving the performances of the array substrate 20. The third conducting regions 321, the first active part 310, and the third active part 330 are doped with one or two combinations of phosphorus or arsenic, thereby further improving electrical properties of the third conducting regions 321, the first active part 310, and the third active part 330.

In an embodiment, a doping concentration of the third channel region 322 is less than a doping concentration of the third conducting regions 321. The doping concentration of the third conducting regions 321 is less than a doping concentration of the fourth conducting regions.

In an embodiment, a planar shape of the second light-shielding part 210 is provided with a third protrusion 221. A protruding direction of the third protrusion 221 is perpendicular to a lateral extending direction of the third channel region 322, and the third protrusion 221 is positioned in an area of the second light-shielding part 220 corresponding to the third conducting regions 321.

In an embodiment, the planar shape of the second light-shielding part 210 is provided with the third protrusion 221. The protruding direction of the third protrusion 221 is perpendicular to the lateral extending direction of the third channel region 322. The third protrusion 221 is positioned in an area of the second light-shielding part 220 corresponding to the third conducting regions 321 and the third channel region 322.

In an embodiment, an edge of an orthographic projection 301 of an area of the active layer 300 excluding the third conducting regions 321 overlaps the edge of the orthographic projection 201 of the light-shielding layer 200. The area of the active layer 300 excluding the third conducting regions 321 includes the first active part 310 and the third active part 330.

In an embodiment, at least a distance D from an edge of an orthographic projection 301 of the third conducting regions 321 on the substrate 100 to the edge of the orthographic projection 201 of the light-shielding layer 200 on the substrate 100 ranges from 400 nm to 2,000 nm. In the present disclosure, by at least setting the distance D from the edge of the orthographic projection 301 of the third conducting regions 321 on the substrate 100 to the edge of the orthographic projection 201 of the light-shielding layer 200 on the substrate 100 to range from 400 nm to 2,000 nm, the light-shielding layer 200 can be allowed to exactly cover the third conducting regions 321, thereby improving the light-shielding effect of the light-shielding layer 200 and reducing cost at a same time.

In an embodiment, at least distances D from the edge of the orthographic projection 301 of the third conducting regions 321 on the substrate 100 and an edge of an orthographic projection 301 of the third channel region 322 on the substrate 100 to the edge of the orthographic projection 201 of the light-shielding layer 200 on the substrate 100 both range from 400 nm to 2,000 nm. The distance L from the edge of the orthographic projection 301 of the active layer 300 on the substrate 100 to the edge of the orthographic projection 201 of the light-shielding layer 200 on the substrate 100 is set to be 0 nm.

In the present disclosure, by setting the distances D from the edge of the orthographic projection 301 of the third conducting regions 321 on the substrate 100 and the edge of the orthographic projection 301 of the third channel region 322 on the substrate 100 to the edge of the orthographic projection 201 of the light-shielding layer 200 on the substrate 100 both to range from 400 nm to 2,000 nm, the light-shielding layer 200 can be allowed to exactly cover the active layer 300, thereby further improving the light-shielding effect of the third conducting regions 321 and the third channel region 322, reducing cost, and preventing junctions between the third conducting regions 321 and the third channel region 322 from breaking at a same time.

The gate electrode 600 is disposed on the third channel region 322.

The array substrate 20 of the present disclosure can be applied to mobile phones, displays, computers, and televisions.

Referring to FIGS. 5, 6, and 12, FIG. 5 is the schematic top view of the array substrate according to the second embodiment of the present disclosure. FIG. 6 is the schematic cross-sectional diagram of the array substrate along the line DE in FIG. 5. FIG. 12 is a flowchart of a manufacturing method of the array substrate according to an embodiment of the present disclosure. The present disclosure further provides the manufacturing method of the array substrate 20, which is specifically described as follows.

Step B21: providing the substrate.

Pre-clean the substrate 100. The material of the substrate 100 may be polyimide or glass.

Step B22: forming the light-shielding layer on the substrate.

Specifically, the material of the light-shielding layer 200 is deposited on the substrate 100 to form a patterned light-shielding layer 200 by exposure and etching. Specifically, the light-shielding layer 200 includes the first light-shielding part 210, the second light-shielding part 220, the third light-shielding part 230, and the fourth light-shielding part 240. The first light-shielding part 210, the second light-shielding part 220, and the third light-shielding part 230 are connected to each other in sequence. The first light-shielding part 210, the third light-shielding part 230, and the fourth light-shielding part 240 are positioned on the same side of the second light-shielding part 220. The first light-shielding part 210 and the third light-shielding part 230 are disposed opposite to each other. The fourth light-shielding part 240 is positioned between the first light-shielding part 210 and the third light-shielding part 230. The material of the light-shielding layer 200 includes the metal material and the insulating material. Wherein, the metal material may be one or more combinations of Al, Cu, Ag, Au, Mn, Zn, or Fe. The thickness H of the light-shielding layer 200 ranges from 50 nm to 500 nm. Specifically, the thickness H of the light-shielding layer 200 may be 50 nm, 52 nm, 70 nm, 200 nm, 350 nm, 430 nm, 470 nm, 490 nm, or 500 nm.

In the present disclosure, the light-shielding layer 200 includes the first light-shielding part 210, the second light-shielding part 220, the third light-shielding part 230, and the fourth light-shielding part 240, which can increase the light-shielding range of the light-shielding layer 200 and further improve the light-shielding effect, thereby ensuring the performances of the array substrate 20.

In an embodiment, after the step B22, the method further includes a following step:
etching the light-shielding layer 200 to remove the fourth light-shielding part 240.

In the present disclosure, removing the fourth light-shielding part 240 and disposing the first light-shielding part 210 and the third light-shielding part 230 on the same side of the second light-shielding part 220 can simplify the manufacturing process, improve the aperture ratio of the pixels, and reduce the production cost.

In an embodiment, after the step of etching the light-shielding layer 200 to remove the fourth light-shielding part 240, the method further includes a following step:

depositing the material of the buffer layer 400 on the light-shielding layer 200 to form the buffer layer 400. The buffer layer 400 includes one or more combinations of SiNₓ, SiOₓ, or SiOₓN_{y}.

Step B23: forming the active layer on the light-shielding layer. Wherein, the orthographic projection of the active layer on the substrate is positioned within the orthographic projection of the light-shielding layer on the substrate.

Specifically, depositing the material of the active layer 300 on the buffer layer 400 to form the active layer 300 by exposure and etching. Wherein, the orthographic projection 301 of the active layer 300 on the substrate 100 is positioned within the orthographic projection 201 of the light-shielding layer 200 on the substrate 100. The active layer 300 includes the first active part 310, the second active part 320, and the third active part 330 connected to each other in sequence. The first active part 310 is disposed on the first light-shielding part 210. The second active part 320 is disposed on the second light-shielding part 220. The third active part 330 is disposed on the third light-shielding part 230. The thickness h of the active layer 300 ranges from 30 nm to 70 nm. The thickness h of the active layer 300 may be 30 nm, 31 nm, 35 nm, 38 nm, 46 nm, 50 nm, 60 nm, 64 nm, 68 nm, or 70 nm.

In an embodiment, after the step B23, the method further includes a following step:

using a barrier layer to block an area of the active layer excluding a first channel region to be made and a second channel region to be made, and doping the first channel region to be made and the second channel region to be made to form the first channel region 312 and the second channel region 332. The first channel region 312 is disposed on the first light-shielding part 210. The second channel region 332 is disposed on the third light-shielding part 230.

In an embodiment, after the step of B23 of forming the first channel region 312 and the second channel region 332 on the first active part 310 above the first light-shielding part 210 and on the third active part 330 above the third light-shielding part 230, respectively, the method further includes a following step:

depositing the material of the insulating layer 500 and the material of the gate electrode 600 on the active layer 300 stacked in sequence and etching to form the insulating layer 500 and the gate electrode 600. The gate electrode 600 is disposed on the first active part 310 and the third active part 330. The material of the insulating layer 500 includes one or more combinations of SiO₂ or SiₓN_{y}. The material of the gate electrode 600 includes one or more combinations of Al, Cu, Ag, Au, Mn, Zn, or Fe.

In an embodiment, after the step of disposing the insulating layer 500 and the gate electrode 600 on the active layer 300 stacked in sequence, the method further includes a following step:

using the gate electrode 600 as a barrier to block the first channel region 312 and the second channel region 332, and then doping an area excluding the first channel region 312 and the second channel region 332 to form the first conducting regions 311, the connecting and conducting region, and the second conducting regions 331. The first conducting regions 311 are disposed on the first light-shielding part 210. The first conducting regions 311 are disposed on the both ends of the first channel region 312. The connecting and conducting region is disposed on the second light-shielding part 220. The second conducting regions 331 are disposed on the third light-shielding part 230. The second conducting regions 331 are disposed on the both ends of the second channel region 332.

Then using another barrier layer to block partial areas of the first conducting regions 311 and the second conducting regions 331, and doping other areas of the first conducting regions 311 and the second conducting regions 331 that are not blocked by the barrier layer to form the second doped regions 3112 and the fourth doped regions 3312. The partial areas of the first conducting regions 311 and the second conducting regions 331 that are blocked by the barrier layer form the first doped regions 3111 and the third doped regions 3311.

The first doped regions 3111, the second doped regions 3112, and the first channel region 312 are disposed on the first light-shielding part 210. The first doped regions 3111 are disposed on the both ends of the first channel region 312. The second doped regions 3112 are disposed on the both ends of the first doped regions 3111 away from the first channel region 312.

The third doped regions 3311, the fourth doped regions 3312, and the second conducting region 331 are disposed on the third light-shielding part 230.

The third doped regions 3311 are disposed on the both ends of the second channel region 332. The fourth doped regions 3312 are disposed on the both ends of the third doped regions 3311 away from the second channel region 332.

In an embodiment, after the step of doping the active layer 300 to form the first doped regions 3111, the second doped regions 3112, the first channel region 312, the third doped regions 3311, the fourth doped regions 3312, and the second channel region 332, the method further includes a following step:

depositing the material of the passivation layer 700 and the material of the source and drain electrode layer 800 on the gate electrode 600 in sequence and etching to form the passivation layer 700 and the source and drain electrode layer 800. The passivation layer 700 is defined with the through-hole 701. The through-hole 701 penetrates through the passivation layer 700 and the insulating layer 500 to expose the active layer 300. The source and drain electrode layer 800 extends into the through-hole 701 to be electrically connected to the active layer 300. The material of the source and drain electrode layer 800 includes one or more combinations of Al, Cu, Ag, Au, Mn, Zn, or Fe.

The present disclosure provides the array substrate and the manufacturing method thereof. The array substrate includes the substrate, the light-shielding layer, and the active layer. The light-shielding layer is disposed on the substrate, and the active layer is disposed on the light-shielding layer. Wherein, the orthographic projection of the active layer on the substrate is positioned within the orthographic projection of the light-shielding layer on the substrate. By allowing the orthographic projection of the active layer on the substrate to be positioned within the orthographic projection of the light-shielding layer on the substrate, the present disclosure prevents the active layer from forming ramps and then breaking and further prevents the electrical deterioration of the array substrate, thereby ensuring the performances of the array substrate.

The embodiments provided by the present disclosure are described in detail above. The specific examples are applied in the description to explain the principle and implementation of the disclosure. The description of the above embodiments is only for helping to understand the technical solution of the present disclosure and its core ideas, and it is understood that many changes and modifications to the described embodiment can be carried out without departing from the scope and the spirit of the disclosure that is intended to be limited only by the appended claims.

What is claimed is:

1. An array substrate, comprising:
a substrate;
a light-shielding layer disposed on the substrate; and
an active layer disposed on the light-shielding layer, wherein an orthographic projection of the active layer on the substrate is positioned within an orthographic projection of the light-shielding layer on the substrate.

2. The array substrate according to claim 1, wherein the light-shielding layer comprises a first light-shielding part, a second light-shielding part, and a third light-shielding part connected to each other in sequence, and the first light-shielding part and the third light-shielding part are positioned on a same side of the second light-shielding part and opposite to each other.

3. The array substrate according to claim 2, wherein the active layer comprises a first active part, a second active part, and a third active part connected to each other in sequence, the first active part is disposed on the first light-shielding part, the second active part is disposed on the second light-shielding part, and the third active part is disposed on the third light-shielding part.

4. The array substrate according to claim 3, wherein the first active part comprises first conducting regions and a first channel region, the first conducting regions are disposed on both ends of the first channel region, the third active part comprises second conducting regions and a second channel region, and the second conducting regions are disposed on both ends of the second channel region.

5. The array substrate according to claim 4, wherein the first conducting regions comprise first doped regions and second doped regions, the first doped regions are disposed on the both ends of the first channel region, the second doped regions are disposed on both ends of the first doped regions away from the first channel region, and a doping concentration of the first doped regions is less than a doping concentration of the second doped regions.

6. The array substrate according to claim 5, wherein the second conducting regions comprise third doped regions and fourth doped regions, the third doped regions are disposed on the both ends of the second channel region, the fourth doped regions are disposed on both ends of the third doped regions away from the second channel region, and a doping concentration of the third doped regions is less than a doping concentration of the fourth doped regions.

7. The array substrate according to claim 6, wherein a planar shape of the first light-shielding part is provided with a first protrusion, a protruding direction of the first protrusion is perpendicular to an extending direction of the first channel region, and the first protrusion is positioned in an area of the first light-shielding part corresponding to the first doped regions; and a planar shape of the third light-shielding part is provided with a second protrusion, a protruding direction of the second protrusion is perpendicular to an extending direction of the second channel region, and the second protrusion is positioned in an area of the third light-shielding part corresponding to the third doped regions.

8. The array substrate according to claim 7, wherein an edge of an orthographic projection of an area of the active layer excluding the first doped regions and the third doped regions overlaps an edge of the orthographic projection of the light-shielding layer.

9. The array substrate according to claim 2, wherein the light-shielding layer further comprises a fourth light-shielding part connected to the first light-shielding part, the second light-shielding part, and the third light-shielding part.

10. The array substrate according to claim 9, wherein the first light-shielding part, the third light-shielding part, and the fourth light-shielding part are positioned on the same side of the second light-shielding part, and the fourth light-shielding part is disposed between the first light-shielding part and the third light-shielding part.

11. The array substrate according to claim 1, wherein the light-shielding layer comprises a first light-shielding part, a second light-shielding part, and a third light-shielding part connected to each other in sequence, and the first light-shielding part and the third light-shielding part are positioned on different sides of the second light-shielding part.

12. The array substrate according to claim 11, wherein the active layer comprises a first active part, a second active part, and a third active part connected to each other in sequence, the first active part is disposed on the first light-shielding part, the second active part is disposed on the second light-shielding part, and the third active part is disposed on the third light-shielding part.

13. The array substrate according to claim 12, wherein the second active part comprises third conducting regions and a third channel region, the third conducting regions are disposed on both ends of the third channel region, and the first active part and the third active part are fourth conducting regions.

14. The array substrate according to claim 13, wherein the second light-shielding part is provided with a third protrusion, a protruding direction of the third protrusion is perpendicular to an extending direction of the third channel region, and the third protrusion is positioned in an area of the second light-shielding part corresponding to the third conducting regions.

15. The array substrate according to claim 14, wherein an edge of an orthographic projection of an area of the active layer excluding the third conducting regions overlaps an edge of the orthographic projection of the light-shielding layer.

16. The array substrate according to claim 13, wherein a doping concentration of the third channel region is less than a doping concentration of the third conducting regions, and the doping concentration of the third conducting regions is less than a doping concentration of the fourth conducting regions.

17. The array substrate according to claim 13, wherein a distance from an edge of an orthographic projection of the third conducting regions on the substrate to an edge of the orthographic projection of the light-shielding layer on the substrate ranges from 400 nm to 2,000 nm.

18. The array substrate according to claim 6, wherein distances from an edge of an orthographic projection of the first doped regions on the substrate and an edge of an orthographic projection of the third doped regions on the substrate to an edge of the orthographic projection of the light-shielding layer on the substrate both range from 400 nm to 2,000 nm.

19. The array substrate according to claim 1, wherein a distance from an edge of the orthographic projection of the active layer on the substrate to an edge of the orthographic projection of the light-shielding layer on the substrate ranges from 0 nm to 6,000 nm.

20. The array substrate according to claim 1, wherein a thickness of the active layer ranges from 30 nm to 70 nm.
